(19) United States
(12) Patent Application Publication
(10) Pub. No.: US 2025/0344590 A1
(43) Pub. Date: Nov. 6, 2025

(54) DISPLAY APPARATUS INCLUDING TEST SAMPLE PATTERN AND METHOD OF MANUFACTURING THE SAME

(71) Applicant: Samsung Display Co., Ltd., Yongin-Si (KR)

(72) Inventors: Dong Hyun KIM, Yongin-si (KR); Hyun-Chol BANG, Yongin-si (KR); Chulkyu KANG, Yongin-si (KR); Su Jin KIM, Yongin-si (KR); Seon-Kyoon MOK, Yongin-si (KR)

(21) Appl. No.: 18/884,110

(22) Filed: Sep. 13, 2024

(30) Foreign Application Priority Data
May 3, 2024 (KR) 10-2024-0059259

(51) Int. Cl. H10K 59/131; H10K 59/12; H10K 59/80; H10K 71/70

(52) U.S. Cl. CPC H10K 59/1315; H10K 59/1201; H10K 59/873; H10K 71/70

(57) ABSTRACT

A display apparatus is disclosed that includes a display substrate, a test sample pattern, connection pads, test pads, and pad connection lines. The display substrate is partitioned into a display area and a non-display area surrounding the display area and includes a conductive wiring, a pixel electrode, and a common electrode disposed in the display area, and an organic encapsulation layer covering the conductive wiring, the pixel electrode, and the common electrode. The test sample pattern is disposed in the non-display area, formed of a same material on a same layer as the common electrode, and covered by the organic encapsulation layer. The connection pads contact the test sample pattern and are separate from each other. The test pads are disposed in a position outside the organic encapsulation layer in the non-display area. The pad connection lines connect the connection pads and the test pads.

### CROSS-REFERENCE TO RELATED APPLICATION

This application claims priority to and the benefit of Korean Patent Application No. 10-2024-0059259 filed in the Korean Intellectual Property Office on May 3, 2024, the entire contents of which are incorporated herein by reference.

### BACKGROUND

### (a) Field

The present disclosure relates to a display apparatus, and more specifically, it relates to a display apparatus that includes a common electrode resistance measuring part, and a method of manufacturing the display apparatus including the common electrode resistance measuring part.

### (b) Description of the Related Art

Display apparatuses such as an organic light-emitting diode (OLED) displays includes various electrodes. Among them, a common electrode is formed throughout a display area of the display apparatus. Its resistance may greatly affect the operation or power consumption of a display apparatus.

### SUMMARY

Accordingly, it may be desirable to establish test means that can measure the resistance of the common electrode and check whether the resistance of the common electrode is within an appropriate range.

In addition, in order to lower the resistance of the common electrode, a common voltage line can be included within the display area and connected to the common electrode. In this case, the common voltage line is formed together with various conductive elements (gate line, data line, pixel electrode, and the like) of the display apparatus, and a contact is formed in a thin film (i.e., electron injection layer, electron transporting layer, hole transporting layer, hole injection layer, and the like included in the organic emission layer) and then a common electrode deposited such that the common electrode is connected with the common voltage line through the contact hole. In this case, the contact hole may be formed using a laser drilling method, and it may be desirable to check whether the contact hole has been formed correctly.

In addition, a separation groove may be formed to prevent electrical leakage from occurring between neighboring pixel electrodes through an electron injection layer, an electron transporting layer, a hole transporting layer, and a hole injection layer, and it may be desirable to check whether the separation groove is formed correctly.

Embodiments are intended to provide a means to check the resistance of the common electrode.

Embodiments are intended to provide a means to check whether a laser drilling process has been performed normally.

Embodiments are intended to provide a means to check whether the separation groove is formed normally.

A display apparatus according to an embodiment includes: a display substrate that is partitioned into a display area and a non-display area surrounding the display area and comprises a conductive wiring, a pixel electrode, and a common electrode disposed in the display area, and an organic encapsulation layer covering the conductive wiring, the pixel electrode, and the common electrode; a test sample pattern that is disposed in the non-display area, formed of a same material on a same layer as the common electrode, and covered by the organic encapsulation layer; a plurality of connection pads contacting the test sample pattern and separated from each other; a plurality of test pads disposed in a position outside the organic encapsulation layer in the non-display area; and a plurality of pad connection lines connecting the connection pads and the test pads.

The connection pads may be formed of the same material on the same layer as the pixel electrode.

The display apparatus may further include an organic light emitting layer interposed between the test sample pattern and the connection pad.

The organic light emitting layer may include a first contact hole, and the test sample pattern contacts the connection pad through the first contact hole.

The first contact hole may be formed using laser drilling.

The display apparatus may include a separation groove that penetrates at least a part of the test sample pattern and the organic light emitting layer and separates the test sample pattern into a first region pattern and a second region pattern.

The display apparatus may include a dam disposed between the test sample pattern and the test pad.

The dam may include a first spacer and a second spacer, and the second spacer may be higher than the first spacer and disposed closer to the test pad.

The display apparatus may further include a plurality of driving circuits that are disposed in the non-display area and that drive the display apparatus by applying a driving signal to the conductive wire, wherein the test sample pattern, the connection pad, the test pad, and the pad connection line may be disposed in a dummy fan-out region between the plurality of the driving circuits.

The display apparatus may further include a first inorganic encapsulation layer disposed below the organic encapsulation layer and a second inorganic encapsulation layer disposed above the organic encapsulation layer, wherein at least one of the first inorganic encapsulation layer and the second inorganic encapsulation layer may be disposed at the periphery of the test pad and may include a second contact hole exposing at least a part of the test pad.

A display apparatus according to an embodiment includes: a display substrate that includes a display area and a non-display area surrounding the display area; a semiconductor layer disposed on the substrate; a first gate insulating layer disposed on the semiconductor layer; a gate electrode disposed on the first gate insulating layer; a second gate insulating layer disposed on the gate electrode; a storage electrode disposed on the second gate insulating layer; a first insulation layer disposed on the storage electrode; an input electrode and an output electrode that are disposed on the first insulation layer and connected with the semiconductor layer; a second insulation layer disposed on the input electrode and the output electrode; a data line and a driving voltage line that are disposed on the second insulation layer; an interlayer insulation layer disposed on the data line and the driving voltage line; a pixel electrode disposed on the interlayer insulation layer; an organic emission layer disposed on the pixel electrode; a common electrode disposed on the organic emission layer; an encapsulation layer that covers the common electrode and includes at least one organic encapsulation layer; a test sample pattern that is disposed in the non-display area, formed of the same layer on the same layer as the common electrode, and covered by the organic encapsulation layer; a plurality of connection pads that are formed of a same material on a same layer as the pixel electrode, in contact with the test sample pattern, and separated from each other; a plurality of test pads that are formed of the same material on the same layer as the input electrode and disposed outside the organic encapsulation layer of the non-display area; a plurality of pad connection lines each comprising a connection member that is formed of the same material on the same layer as at least one of the gate electrode, the input electrode, and the data line and connecting the connection pads and the test pads.

The connection member may include a first connection member formed of the same material on the same layer as the data line, a second connection member formed of the same material on the same layer as the input electrode, and a third connection member formed of the same material on the same layer as the gate electrode.

The display apparatus may include a dam disposed between the test sample pattern and the test pads.

The third connection member may cross the dam and connect between one of the test pads and the second connection member.

The display apparatus may further include an organic light emitting layer interposed between the test sample pattern and the connection pad.

The organic light emitting layer may include a first contact hole, and the test sample pattern contacts the connection pad through the first contact hole.

The first contact hole may be formed using laser drilling.

The display apparatus may include a separation groove that penetrates at least a part of the test sample pattern and the organic light emitting layer and separates the test sample pattern into a first region pattern and a second region pattern.

A method of manufacturing a display device according to an embodiment includes: preparing a substrate including a plurality of cell regions, each of which is partitioned into a display area and a non-display area surrounding the display area; forming a thin film pattern including a conductive wire, a pixel electrode, and a common electrode in the display area, and a test sample pattern, a plurality of connection pads, a plurality of test pads, and a plurality of pad connection lines in the non-display area; and forming an organic encapsulation layer covering the conductive wire, the pixel electrode, the common electrode, and the test sample pattern, the test sample pattern is formed of a same material on a same layer as the common electrode, the connection pads are in contact with the test sample pattern and separate from each other, the test pads are disposed outside the organic encapsulation layer, and the pad connection lines connect the connection pads to the test pads.

The connection pad may be formed of the same material on the same layer as the pixel electrode, and the method may further include forming an organic light emitting layer between the test sample pattern and the connection pad and forming a contact hole by laser drilling the organic light emitting layer.

According to embodiments, the resistance of the test sample pattern covered by the encapsulation layer can be measured through a test pad placed outside the encapsulation layer to thereby inspect the resistance of the common electrode, whether laser drilling is performed normally, and whether the separation groove is formed normally.

### BRIEF DESCRIPTION OF THE DRAWINGS

FIG. 1 is a layout view of a display apparatus according to an embodiment.

FIG. 2 is an enlarged layout view of region C of FIG. 1.

FIG. 3 is an enlarged layout view of a test pattern area of FIG. 2.

FIG. 4 is an enlarged layout view of a left test sample pattern of FIG. 3.

FIG. 5 is an enlarged layout view of a right test sample pattern of FIG. 3.

FIG. 6 is a cross-sectional view of FIG. 3, taken along the line A-A′.

FIG. 7 is a cross-sectional view of FIG. 3, taken along the line B-B′.

FIG. 8 is a layout view that shows a connection state of a test sample pattern and a test pad of a display apparatus according to an embodiment.

FIG. 9 is a layout view of a test sample pattern and a test pad of a display apparatus according to an embodiment.

FIG. 10 is a layout view that shows a position of a test pattern region in a method of manufacturing a display apparatus according to an embodiment.

### DETAILED DESCRIPTION OF THE EMBODIMENTS

Hereinafter, the present disclosure will be described more fully hereinafter with reference to the accompanying drawings, in which embodiments of the invention are shown. As those skilled in the art would realize, the described embodiments may be modified in various different ways.

In order to clearly describe the present disclosure, parts that are not relevant to the description are omitted, and identical or similar components are assigned the same reference numerals throughout the specification.

In addition, since the size and thickness of each component shown in the drawing are arbitrarily indicated for better understanding and ease of description, the present invention is not necessarily limited to the drawings. In the drawings, the thickness of layers, films, panels, regions, etc., are exaggerated for clarity. In the drawings, the thickness of layers, films, panels, regions, etc., are exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

In addition, unless explicitly described to the contrary, the words “comprise,” “include,” and “have” and variations such as “comprises” or “comprising,” will be understood to imply the inclusion of stated elements but not the exclusion of any other elements.

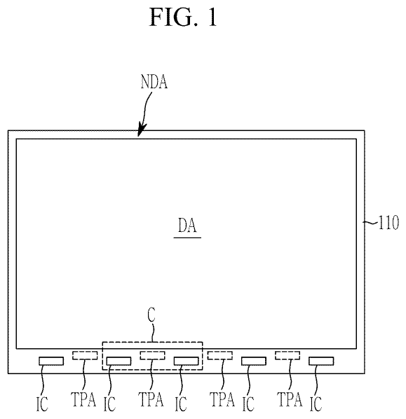

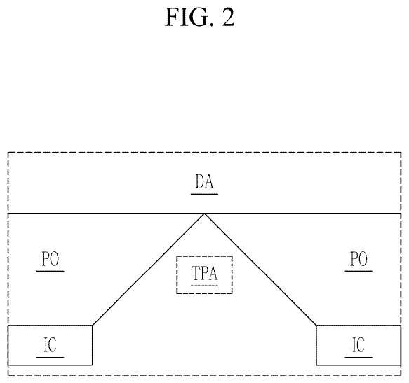

FIG. 1 is a layout view of a display apparatus according to an embodiment. FIG. 2 is an enlarged layout view of region C of FIG. 1.

Referring to FIG. 1, a display apparatus according to an embodiment may include a display substrate 110 and various element pattern layers stacked on the display substrate 110. The display substrate 110 may include a display area DA configured to display an image and a non-display area NDA disposed at the periphery of the display area DA. The display area may include an organic light emitting element including a pixel electrode, a common electrode, and an organic emission layer, a thin film transistor for controlling the operation of the organic light emitting element, a gate line, a data line, and the like. The non-display area NDA may include a driving circuit IC that applies various signals through the gate line and the data line for driving the display apparatus and a test pattern area TPA for testing the resistance of the common electrode, and checking whether a laser drilling process is performed normally and whether a separation groove is formed normally. The driving circuit IC may be an integrated chip mounted on the display substrate 110, or it may be formed on the display substrate 110 through a thin film forming process. The test pattern area TPA may be disposed adjacent to the driving circuit IC or between driving circuits IC. A plurality of test pattern areas TPA may be disposed between the driving circuit ICs or the test pattern areas TPA may be disposed between some of the driving circuits IC.

Referring to FIG. 2, a fan-out area PO where wires connecting between the driving circuit IC and the wires (e.g., the gate line, the data line, and the like) of the display area DA spread out like a fan may be included in the non-display area NDA. The test pattern area TPA may be disposed two neighboring two fan-out areas PO.

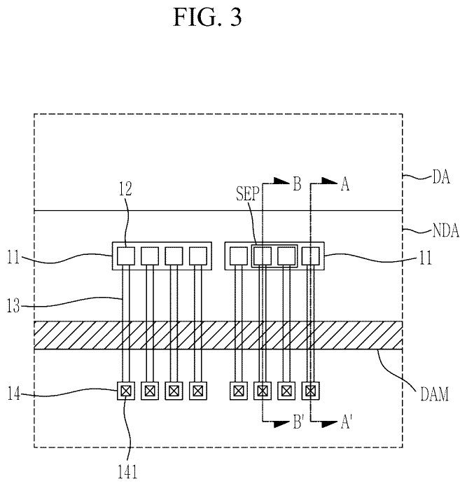

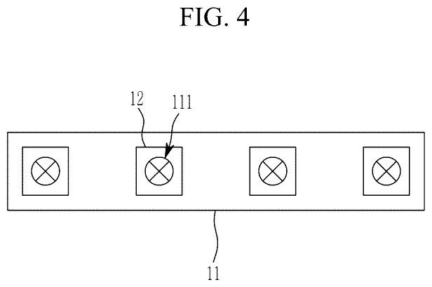

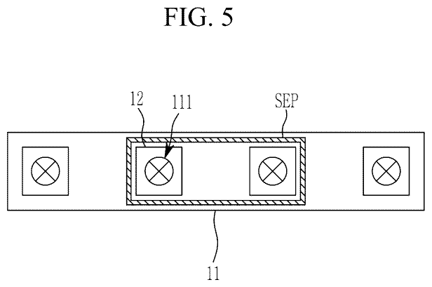

FIG. 3 is an enlarged layout view of the test pattern area TPA of FIG. 2. FIG. 4 is an enlarged layout view of the left test sample pattern 11 of FIG. 3. FIG. 5 is an enlarged layout view of the right test sample pattern 11 of FIG. 3.

Referring to FIG. 3, in a position outside the display area DA, that is, in the non-display area NDA, a dam DAM, which may include a plurality of spacers, may be disposed to surround the display area DA. The dam DAM is disposed at a predetermined distance from the display area DA and may serve to confine an organic material of an organic encapsulation layer.

The test sample pattern 11 and a connection pad 12 may be disposed between the dam DAM and display area DA, and a test pad 14 may be disposed outside the dam DAM. A pad connection line 13 may be disposed across the dam DAM between the connection pad 12 and the test pad 14. The pad connection line 13 is wiring disposed below the dam DAM and may electrically connect between the connection pad 12 and the test pad 14. The connection pad 12 may be electrically connected by directly contacting the test sample pattern 11.

The test sample pattern 11 is formed with the same material on the same layer as the common electrode of the display area DA, and may be formed together in a process (deposition, photolithography, and etching) of forming the common electrode. Thus, the sheet resistance of the common electrode may be estimated by measuring the sheet resistance between a plurality of points of the test sample pattern 11.

The connection pad 12 may be formed of the same material on the same layer as the pixel electrode, and the pad connection line 13 and the test pad 14 may be formed of the same material on the same layer as at least one of the conductive wiring. That is, the connection pad 12 may be formed together in the process of forming the pixel electrode, and the pad connection line 13 and the test pad 14 may be formed together in the process of forming wiring such as the gate line or the data line.

Referring to FIGS. 4 and 5, the connection pad 12 and the test sample pattern 11 may contact each other through a contact hole 111 that penetrates the organic emission layer. The contact hole 111 may be formed through laser drilling.

Referring to FIG. 5, the test sample pattern 11 may be separated into two parts through a separation groove SEP. The separation groove SEP is formed to surround the central two connection pads 12, and thus the test sample pattern 11 may be separated into a part connected to the central two connection pads 12 and other parts.

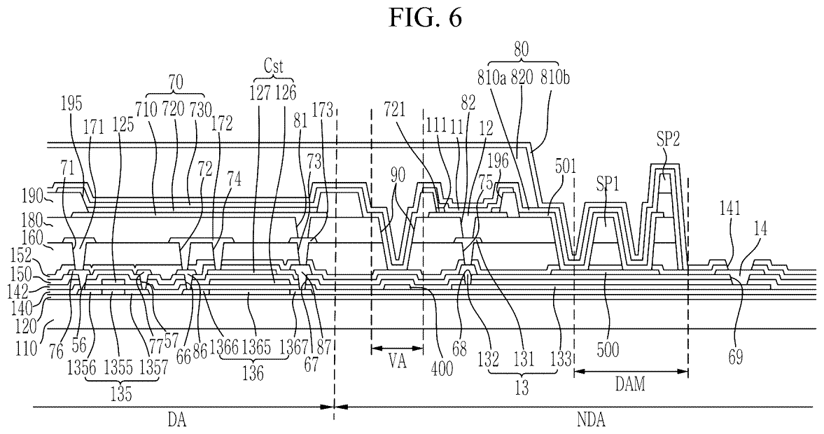

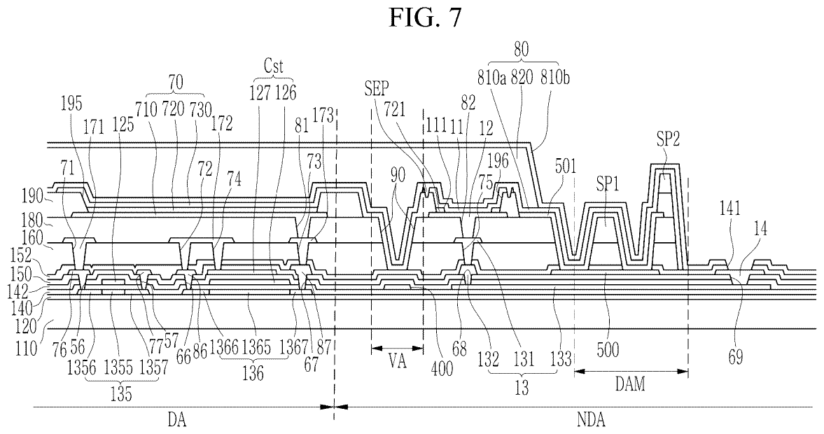

FIG. 6 is a cross-sectional view of FIG. 3, taken along the line A-A′, and FIG. 7 is a cross-sectional view of FIG. 3, taken along the line B-B′.

Referring to FIGS. 3, 6, and 7, the display apparatus according to an embodiment includes a substrate 110, and the substrate 110 may be flexible. Although it is not illustrated, the substrate 110 may include a plurality of insulation films that overlap each other, and may further include a barrier film disposed between the overlapped insulation films.

A buffer layer 120 may be disposed on the substrate 110. The buffer layer 120 may include a single insulation layer such as silicon nitride (SiNₓ) and silicon oxide (SiOₓ) or a plurality of multilayers of silicon nitride (SiNₓ) and silicon oxide (SiOₓ). The buffer layer 120 may prevent penetration of unnecessary components such as impurity or moisture.

A first semiconductor layer 135 and a second semiconductor layer 136 may be disposed on the buffer layer 120 in the display area DA.

The first semiconductor layer 135 and the second semiconductor layer 136 may include polysilicon or an oxide semiconductor. In this case, the oxide semiconductor may include an oxide based on titanium (Ti), hafnium (Hf), zirconium (Zr), aluminum (Al), tantalum (Ta), germanium (Ge), zinc (Zn), gallium (Ga), tin (Sn), or indium (In) or a composite oxide thereof.

The first semiconductor layer 135 includes a first channel region 1355, and a first source region 1356 and a first drain region 1357 that are respectively disposed at both ends of the first channel region 1355. Similarly, the second semiconductor layer 136 includes a second channel region 1365, and a second source region 1366 and a second drain region 1367 that are respectively disposed at both ends of the second channel region 1365. The first channel region 1355 of the first semiconductor layer 135 and the second channel region 1365 of the second semiconductor layer 136 are regions not doped with an impurity, and the first source region 1356 and the first drain region 1357 of the first semiconductor layer 135 and the second source region 1366 and the second drain region 1367 of the second semiconductor layer 136 may be regions doped with a conductive impurity.

A first gate insulating layer 140 is disposed on the first semiconductor layer 135 and the second semiconductor layer 136.

The first gate electrode 125 and the second gate electrode 126 are disposed on the first gate insulating layer 140 of the display area DA, and a first auxiliary member 400 may be disposed on the first gate insulating layer 140 in a blocking area VA of the non-display area NDA. In addition, the third connection member 133 may be disposed outside the blocking area VA of the non-display area NDA. The third connection member 133 may cross a region of the dam DAM. The first gate electrode 125 and the second gate electrode 126 may be referred to as a first gate wire.

The first gate electrode 125 overlaps the first channel region 1355, and the second gate electrode 126 overlaps the second channel region 1365. The first auxiliary member 400 and the third connection member 133 may be simultaneously formed in the same layer as the first gate electrode 125 and the second gate electrode 126.

A second gate insulating layer 142 is disposed on the first gate electrode 125, the second gate electrode 126, the first auxiliary member 400, and the third connection member 133.

The first gate insulating layer 140 and the second gate insulating layer 142 each may be a single layer containing silicon oxide (SiOₓ) and silicon nitride (SiNₓ), or a multilayer formed by stacking the same.

A storage electrode 127 may be disposed on the second gate insulating layer 142. The storage electrode 127 is referred to as a second gate wire.

A first insulation layer 150 is disposed on the storage electrode 127. The first insulation layer 150 may be a single layer containing silicon oxide (SiOₓ) and silicon nitride (SiNₓ), or a multilayer formed by stacking the same.

Each of a first contact hole 56 overlapping a first source region 1356 of the first semiconductor layer 135, a second contact hole 57 overlapping a first drain region 1357 of the first semiconductor layer 135, a third contact hole 66 overlapping a second source region 1366 of the second semiconductor layer 136, a fourth contact hole 67 overlapping a second drain region 1367 of the second semiconductor layer 136, and a fifth contact hole 68 and a sixth contact hole 69 overlapping a third connection member 133 may extend through the first gate insulating layer 140, the second gate insulating layer 142, and the first insulation layer 150.

A first input electrode 76, a first output electrode 77, a second input electrode 86, and a second output electrode 87 are formed on the first insulation layer 150 of the display area DA. A common voltage transmission line 500, a second connection member 132, and a test pad 14 are formed on the first insulation layer 150 of the non-display area NDA. The first input electrode 76, the first output electrode 77, the second input electrode 86, and the second output electrode 87 may be referred to as first data wiring.

The common voltage transmission line 500, the second connection member 132, and the test pad 14 may be simultaneously formed in the same layer as the first input electrode 76, the first output electrode 77, the second input electrode 86, and the second output electrode 87.

The first input electrode 76 is connected with the first source region 1356 of the first semiconductor layer 135 through the first contact hole 56, the first output electrode 77 is connected with the first drain region 1357 of the first semiconductor layer 135 through the second contact hole 57, the second input electrode 86 is connected with the second source region 1366 of the second semiconductor layer 136 through the third contact hole 66, and the second output electrode 87 is connected with the second drain region 1367 of the second semiconductor layer 136 through the fourth contact hole 67. Although it is not illustrated, the first output electrode 77 is connected to the second gate electrode 126. The second connection member 132 is connected to one end of the third connection member 133 through the fifth contact hole 68, and the test pad 14 is connected to the other end of the third connection member 133 through the sixth contact hole 69.

The second insulation layer 152 is disposed on the first input electrode 76, the first output electrode 77, the second input electrode 86, the second output electrode 87, the common voltage transmission line 500, the second connection member 132, and the test pad 14. The second insulation layer 152 may be a single layer containing silicon oxide (SiOₓ) and silicon nitride (SiNₓ), or a multilayer formed by stacking the same.

The first interlayer insulation layer 160 is disposed on the second insulation layer 152. The first interlayer insulation layer 160 may include an organic material. A seventh contact hole 71 overlapping the first input electrode 76, an eighth contact hole 72 overlapping the second input electrode 86, a ninth contact hole 73 overlapping the second output electrode 87, and a tenth contact hole 75 overlapping the second connection member 132 are formed in the first interlayer insulation layer 160 and the second insulation layer 152. An eleventh contact hole 74 overlapping the storage electrode 127 is formed in the first insulation layer 150, the second insulation layer 152, and the first interlayer insulation layer 160.

A data line 171, a driving voltage line 172, and an output member 173 may be disposed on the first interlayer insulation layer 160. In addition, the first connection member 131 may be disposed on the first interlayer insulation layer 160. The data line 171, the driving voltage line 172, and the output member 173 may be referred to as second data wiring.

The data line 171 is connected with the first input electrode 76 through the seventh contact hole 71, and the driving voltage line 172 is connected with the second input electrode 86 through the eighth contact hole 72 and connected with the storage electrode 127 through the eleventh contact hole 74. The output member 173 may be connected with the second output electrode 87 through the ninth contact hole 73, and the first connection member 131 may be connected with the second connection member 132 through the tenth contact hole 75.

A second interlayer insulation layer 180 is disposed on the data line 171, the driving voltage line 172, the output member 173, and the first connection member 131. The second interlayer insulation layer 180 may include an organic material.

A twelfth contact hole 81 overlapping the output member 173 and a thirteenth contact hole 82 overlapping the first connection member 131 are formed in the second interlayer insulation layer 180.

A groove 90 is formed in the first interlayer insulation layer 160 and the second interlayer insulation layer 180 disposed in the blocking area VA of the non-display area NDA. The blocking area VA overlaps with an encapsulation layer 80, which will be described later. The groove 90 overlaps a first auxiliary member 400 disposed on the blocking area VA.

The groove 90 is formed to surround the display area DA, and external moisture and air that may inflow can be prevented from flowing into the display area DA through the first interlayer insulation layer 160 and the second interlayer insulation layer 180 disposed in the non-display area NDA.

A pixel electrode 710 is disposed on the second interlayer insulation layer 180 disposed in the display area DA. The pixel electrode 710 is connected to the output member 173 through the twelfth contact hole 81 formed in the second interlayer insulation layer 180. The pixel electrode 710 may be an anode of the organic light emitting element.

The first electrode member 501 in contact with the common voltage transmission line 500 and the connection pad 12 in contact with the first connection member 131 may be disposed on the second interlayer insulation layer 180 in the non-display area NDA. The first electrode member 501 and the connection pad 12 may be formed simultaneously in the same layer as the pixel electrode 710.

A pixel definition layer 190 may be disposed on the pixel electrode 710 and the connection pad 12. The pixel definition layer 190 may have a first opening 195 that overlaps the pixel electrode 710 and a second opening 196 that overlaps the connection pad 12. The first opening 195 of the pixel definition layer 190 is disposed in the display area DA, and the second opening 196 is disposed in the non-display area NDA. The pixel definition layer 190 may include resin such as polyacrylates or polyimides and silica-based inorganic materials. The pixel definition layer 190 is mainly positioned in the display area DA, and may not be positioned above the connection pad 12. In this case, the second opening 196 also does not exist.

The organic emission layer 720 may be disposed in a first opening 195 of the pixel definition layer 190, and a residual organic emission layer 721 may be disposed in a second opening 196.

The organic emission layer 720 and the residual organic emission layer 721 may be multiple layers including one or more of a light emission layer, a hole injection layer (HIL), a hole transporting layer (HTL), an electron transporting layer (ETL), and an electron injection layer (EIL). When the organic emission layer 720 includes all of these, the hole injection layer is disposed on the pixel electrode 710, which is an anode, and the hole transporting layer, the light emission layer, the electron transporting layer, and the electron injection layer may be stacked sequentially. The residual organic emission layer 721 may include a hole injection layer (HIL), a hole transporting layer (HTL), an electron transporting layer (ETL), and an electron injection layer (EIL), and may not include a light emission layer.

A fourteenth contact hole 111 formed through laser drilling is formed in the residual organic emission layer 721. Although not shown, contact holes that are formed through laser drilling and penetrate at least a part of the organic emission layer may be disposed in the display area DA. These contact holes overlap a common voltage connection member (not shown, which may have a similar structure to the connection pad 12 and the pad connection line 13) formed where the pixel electrode 710 is not disposed. The common voltage connection member may be connected with the common voltage transmission line 500 through connection wiring. At least a part of the organic emission layer where contact holes overlap the common voltage connection member may include a hole injection layer, a hole transporting layer, an electron transporting layer, and an electron injection layer, and may not include an emission layer.

A common electrode 730 is disposed on the pixel definition layer 190 and the organic emission layer 720, and a test sample pattern 11 is disposed on the residual organic emission layer 721. The common electrode 730 becomes a cathode of the organic light emitting element. Therefore, the pixel electrode 710, the organic emission layer 720, and the common electrode 730 form an organic light emitting element 70. The test sample pattern 11 may contact the connection pad 12 through the fourteenth contact hole 111.

It is possible to check whether the laser drilling process is performed normally by allowing the test sample pattern 11 to contact the connection pad 12 through the fourteenth contact hole formed through laser drilling. When the laser drilling process is not performed properly, the test sample pattern 11 and the connection pad 12 do not make contact, resulting in a significant increase in resistance.

Depending on embodiments, the residual organic emission layer 721 may not be included. When there is no need to check whether the laser drilling process is performed normally, the residual organic emission layer 721 is omitted.

Depending on a direction in which the organic light emitting element 70 emits light, an organic light-emitting diode (OLED) display may have any of the following structures: front display type, rear display type, and double-sided display type.

In the case of the front display type, the pixel electrode 710 may be a reflective layer and the common electrode 730 may be a semi-transmissive film or a transmissive film. On the other hand, in the case of the rear display type, the pixel electrode 710 may be a semi-transmissive layer and the common electrode 730 may be a reflective film. In addition, in the case of the double-sided display type, the pixel electrode 710 and the common electrode 730 may be transparent or semi-transparent films. The reflective layer and semi-permeable membrane may be formed of one or more metals of magnesium (Mg), silver (Ag), gold (Au), calcium (Ca), lithium (Li), chromium (Cr), and aluminum (Al), or alloys thereof. The reflective film and the semi-transparent layer film determined by their thickness, and the semi-transparent film may be formed with a thickness of 200 nm or less. The thinner the thickness, the higher the light transmittance, but if it is too thin, the resistance increases. The transparent film may include indium tin oxide (ITO), indium zinc oxide (IZO), zinc oxide (ZnO), or indium oxide (indium oxide).

The common electrode 730 is formed in front of the display area DA, extends to the non-display area NDA, and contacts the first electrode member 501.

The common electrode 730 receives a common voltage transmitted to the common voltage transmission line 500 through the first electrode member 501 that is in contact with the common voltage transmission line 500. The common electrode 730 may also receive a common voltage through a common voltage connection member formed in a location where the pixel electrode 710 in the display area DA is not positioned.

When a gate-on signal is applied to the first gate electrode 125 and a data signal from the data line 171 is applied to the first input electrode 76, the data signal is transmitted to the first output electrode 77 and then to the second gate electrode 126. In addition, the driving voltage applied to the driving voltage line 172 is applied to the second input electrode 86 and to the second output electrode 87 through the second channel region 1365 of the second semiconductor layer 136. A voltage applied to the second output electrode 87 is transmitted to the pixel electrode 710 through the output member 173, and the common voltage is applied to the common electrode 730 through the common voltage transmission line 500. The pixel electrode 710 is an anode, which is a hole injection electrode, and the common electrode 730 is a cathode, which is an electron injection electrode. Holes and electrons are injected into the organic emission layer 720 from the pixel electrode 710 and the common electrode 730, respectively, and light emission occurs when the exciton combined with the injected hole and electron falls from the exited state to the ground state.

A capacitor Cst is formed by the second gate electrode 126 and the storage electrode 127. The capacitor Cst charges and maintains the data signal applied to the second gate electrode 126.

A first spacer SP1 and a second spacer SP2 are disposed in an outer portion of the non-display area NDA, and they form the dam DAM. The first spacer SP1 overlaps the common voltage transmission line 500, and the second spacer SP2 is disposed farther from the display area DA than the first spacer SP1. In other words, the second spacer SP2 is disposed on an outer side from the first spacer SP1.

The first spacer SP1 may be formed of a layer such as the first interlayer insulation layer 160 and the second interlayer insulation layer 180 that are also disposed in the display area DA, and the second spacer SP2 may be formed of an insulation layer such as the first interlayer insulation layer 160, the second interlayer insulation layer 180, and the pixel definition layer 190 that are also disposed in the display area DA and an additional insulation layer.

An encapsulation layer 80 is disposed on the common electrode 730 and the test sample pattern 11. The encapsulation layer 80 may be formed by stacking one or more inorganic layers and one or more organic layers alternating with each other, and the number of inorganic layers or the organic layers may be plural.

In the illustrated embodiment, the encapsulation layer 80 includes a first inorganic encapsulation layer 810a and a second inorganic encapsulation layer 810b, and includes an organic encapsulation layer 820 disposed between the first inorganic encapsulation layer 810a and the second inorganic encapsulation layer 810b.

The first inorganic encapsulation layer 810a and the second inorganic encapsulation layer 810b may be formed on the entire substrate 110 and are disposed on the first spacer SP1 and the second spacer SP2, but the organic encapsulation layer 820 is not located outside the first spacer SP1 and the second spacer SP2 in the non-display area NDA. The first inorganic encapsulation layer 810a and the second inorganic encapsulation layer 810b include an inspection contact hole 141 disposed outside the second spacer SP2. The test pad 14 is exposed through the test contact hole 141, and the test may be performed by contacting a test probe with the test pad 14.

When forming the organic encapsulation layer 820, the first spacer SP1 and the second spacer SP2 may serve as a dam DAM to prevent an organic material from overflowing, and since the organic material does not overflow into the outer edges of the first spacer SP1 and the second spacer SP2, the organic encapsulation layer 820 may be formed not to be disposed outside the first spacer SP1 and the second spacer SP2.

The groove 90 is formed in the first interlayer insulation layer 160 and the second interlayer insulation layer 180 that are disposed in the blocking area VA of the non-display area NDA, and the groove 90 formed in the blocking area VA overlaps the first inorganic encapsulation layer 810a, the second inorganic encapsulation layer 810b, and the organic encapsulation layer 820 of the thin film encapsulation layer 80.

The groove 90 is formed in the first interlayer insulation layer 160 and the second interlayer insulation layer 180 disposed in the blocking area VA that overlaps the thin film encapsulation layer 80 such that the inflow of external moisture and air into the display area DA covered by the thin film encapsulation layer 80 through the first interlayer insulation layer 160 and the second interlayer insulation layer 180 disposed in the non-display area NDA can be additionally prevented.

In addition, since the groove 90 overlaps with the first auxiliary member 400 disposed in the blocking area VA, a depth of the groove 90 becomes less than a maximum sum of a thickness of the first interlayer insulation layer 160 and a thickness of the second interlayer insulation layer 180. This may prevent organic material from remaining when forming groove 90 by lowering a height of the groove 90 formed in the first interlayer insulation layer 160 and the second interlayer insulation layer 180 disposed in the blocking area VA, and inflow of external moisture and air through the remaining organic material in the groove 90 can be more effectively prevented.

Referring to FIGS. 3, 5, and 7, the test sample pattern 11 is divided into two portions through the separation groove SEP. The separation groove SEP may be a groove formed by extending through the test sample pattern 11 and partially extending into the pixel definition layer 190 below the test sample pattern 11. Although not shown, the separation groove SEP may also penetrate and separate the organic emission layer. In particular, like the common electrode 730, a hole injection layer (HIL), a hole transporting layer (HTL), an electron transporting layer (ETL), and an electron injection layer (EIL) may be formed in the entire area surrounded by the dam DAM, and these layers may cause current leakage of the pixel electrode 710. To prevent the current leakage, the separation groove SEP is formed around the pixel electrode 710 to separate the hole injection layer (HIL), the hole transporting layer (HTL), the electron transporting layer (ETL), and the electron injection layer (EIL) by pixel. The separation groove SEP is also formed in the test sample pattern 11 such that it is possible to check whether the separation grooves SEP are formed normally by measuring whether both sides of the separation groove SEP are electrically connected.

The structure of the pixel disposed in the display area DA of the display device illustrated in FIGS. 6 and 7 is an example, and the pixel structure of the display apparatus according to embodiments is not limited to the structure shown in FIGS. 6 and 7. The signal line and the organic light emitting element may be formed into various structures within a range that can be easily modified by experts in the relevant technical field. For example, in FIGS. 6 and 7, as a display device, a display apparatus using two thin film transistors (TFT) and one capacitor is illustrated, but the present disclosure is not limited thereto. Therefore, in the display apparatus, the number of thin film transistors, the number of capacitors, and the number of wires are not restrictive.

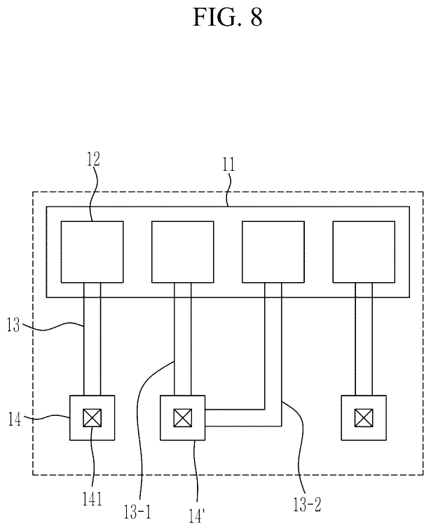

FIG. 8 is a layout view that shows a connection state of the test sample pattern and the test pad of the display apparatus according to an embodiment.

A pad connection line 13 connecting between the connection pad 12 and the test pad 14 may be arranged in various ways depending on embodiments. As previously shown in FIG. 3, the connection pad 12 and the test pad 14 may be connected one to one, and as shown in FIG. 8, some connection pads 12 may be commonly connected to one test pad 14.

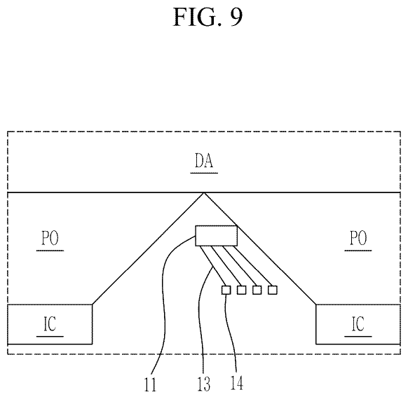

FIG. 9 is a layout view of the test sample pattern and the test pad of the display apparatus according to an embodiment.

The arrangement of the test sample pattern 11, the pad connection line 13, and the test pad 14 may also be arranged in various ways depending on embodiments. As previously shown in FIG. 3, the test sample pattern 11, the pad connection line 13, and the test pad 14 may be formed separately from dummy fan-out wiring, and, as shown in FIG. 9, the pad connection line 13 may be formed using dummy fan-out wiring.

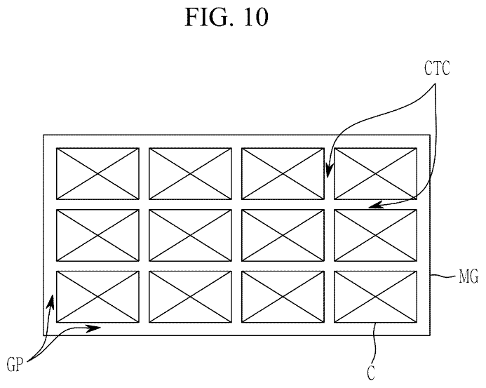

FIG. 10 is a layout view that shows the position of the test pattern region in a method of forming the common electrode resistance measurement portion according to an embodiment.

The test pattern region may be placed within the non-display area NDA of the display apparatus as shown in previous embodiments, and may be disposed in a region CTC between cells C of a mother glass MG or a region not included in the display apparatus, such as an edge portion GP of the mother glass MG as shown in FIG. 10.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A display apparatus comprising:
a display substrate that is partitioned into a display area and a non-display area surrounding the display area and comprises a conductive wiring, a pixel electrode, and a common electrode disposed in the display area, and an organic encapsulation layer covering the conductive wiring, the pixel electrode, and the common electrode;
a test sample pattern that is disposed in the non-display area, formed of a same material on a same layer as the common electrode, and covered by the organic encapsulation layer;
a plurality of connection pads contacting the test sample pattern and separated from each other;
a plurality of test pads disposed in a position outside the organic encapsulation layer in the non-display area; and
a plurality of pad connection lines connecting the connection pads and the test pads.

2. The display apparatus of claim 1, wherein:
the connection pads are formed of the same material on the same layer as the pixel electrode.

3. The display apparatus of claim 2, further comprising an organic light emitting layer interposed between the test sample pattern and the connection pad.

4. The display apparatus of claim 3, wherein:
the organic light emitting layer comprises a first contact hole, and the test sample pattern contacts the connection pad through the first contact hole.

5. The display apparatus of claim 4, wherein:
the first contact hole is formed using laser drilling.

6. The display apparatus of claim 5, further comprising a separation groove that penetrates at least a part of the test sample pattern and the organic light emitting layer and separates the test sample pattern into a first region pattern and a second region pattern.

7. The display apparatus of claim 1, further comprising a dam disposed between the test sample pattern and the test pad.

8. The display apparatus of claim 7, wherein:
the dam comprises a first spacer and a second spacer, and the second spacer is higher than the first spacer and disposed closer to the test pad.

9. The display apparatus of claim 1, further comprising a plurality of driving circuits that are disposed in the non-display area and that drive the display apparatus by applying a driving signal to the conductive wire,
wherein the test sample pattern, the connection pad, the test pad, and the pad connection line are disposed in a dummy fan-out region between the plurality of the driving circuits.

10. The display apparatus of claim 1, further comprising a first inorganic encapsulation layer disposed below the organic encapsulation layer and a second inorganic encapsulation layer disposed above the organic encapsulation layer,
wherein at least one of the first inorganic encapsulation layer and the second inorganic encapsulation layer is disposed at the periphery of the test pad, and includes a second contact hole exposing at least a part of the test pad.

11. A display apparatus comprising:
a display substrate that includes a display area and a non-display area surrounding the display area;
a semiconductor layer disposed on the substrate;
a first gate insulating layer disposed on the semiconductor layer;
a gate electrode disposed on the first gate insulating layer;
a second gate insulating layer disposed on the gate electrode;
a storage electrode disposed on the second gate insulating layer;
a first insulation layer disposed on the storage electrode;
an input electrode and an output electrode that are disposed on the first insulation layer and connected with the semiconductor layer;
a second insulation layer disposed on the input electrode and the output electrode;
a data line and a driving voltage line that are disposed on the second insulation layer;
an interlayer insulation layer disposed on the data line and the driving voltage line;
a pixel electrode disposed on the interlayer insulation layer;
an organic emission layer disposed on the pixel electrode;
a common electrode disposed on the organic emission layer;
an encapsulation layer that covers the common electrode and includes at least one organic encapsulation layer;
a test sample pattern that is disposed in the non-display area, formed of a same material on a same layer as the common electrode, and covered by the organic encapsulation layer;
a plurality of connection pads that are formed of the same material on the same layer as the pixel electrode, in contact with the test sample pattern, and separated from each other;
a plurality of test pads that are formed of the same material on the same layer as the input electrode and disposed outside the organic encapsulation layer of the non-display area;
a plurality of pad connection lines each comprising a connection member that is formed of the same material on the same layer as at least one of the gate electrode, the input electrode, and the data line and connecting the connection pads and the test pads.

12. The display apparatus of claim 11, wherein:
the connection member comprises a first connection member formed of the same material on the same layer as the data line, a second connection member formed of the same material on the same layer as the input electrode, and a third connection member formed of the same material on the same layer as the gate electrode.

13. The display apparatus of claim 12, further comprising a dam disposed between the test sample pattern and the test pads.

14. The display apparatus of claim 13, wherein:
the third connection member crosses the dam and connects between one of the test pads and the second connection member.

15. The display apparatus of claim 11, further comprising an organic light emitting layer interposed between the test sample pattern and the connection pads.

16. The display apparatus of claim 15, wherein:
the organic light emitting layer comprises a first contact hole, and the test sample pattern contacts the connection pad through the first contact hole.

17. The display apparatus of claim 16, wherein:
the first contact hole is formed using laser drilling.

18. The display apparatus of claim 17, further comprising a separation groove that penetrates at least a part of the test sample pattern and the organic light emitting layer and separates the test sample pattern into a first region pattern and a second region pattern.

19. A method of manufacturing a display apparatus, comprising:
preparing a substrate including a plurality of cell regions, each of which is partitioned into a display area and a non-display area surrounding the display area;
forming a thin film pattern including a conductive wire, a pixel electrode, and a common electrode in the display area, and a test sample pattern, a plurality of connection pads, a plurality of test pads, and a plurality of pad connection lines in the non-display area; and
forming an organic encapsulation that covers the conductive wire, the pixel electrode, the common electrode, and the test sample pattern,
wherein:
the test sample pattern is formed of a same material on a same layer as the common electrode,
the connection pads are in contact with the test sample pattern and separate from each other,
the test pads are disposed outside the organic encapsulation layer, and
the pad connection lines connect the connection pads to the test pads.

20. The method of manufacturing a display apparatus of claim 19,
further comprising forming an organic light emitting layer between the test sample pattern and the connection pads; and
forming a contact hole by laser drilling the organic light emitting layer,
wherein the connection pads are formed of the same material on the same layer as the pixel electrode.
